(19) United States
(12) Patent Application Publication
(10) Pub. No.: US 2006/0226531 A1
(43) Pub. Date: Oct. 12, 2006

(54) Power semiconductor module

(76) Inventors: Thomas Passe, Epscheid (DE); Gottfried Ferber, Warstein (DE); Benedikt Specht, Sundern (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/329,571

(22) Filed: Jan. 11, 2006

Related U.S. Application Data
(63) Continuation of application No. PCT/EP04/05450, filed on May 21, 2004.

(30) Foreign Application Priority Data
Jul. 11, 2003 (DE) 103 31 574.8

(51) Int. Cl. H01L 23/52

(52) U.S. Cl. 257/691

(57) ABSTRACT

A semiconductor power module has a support (1), whereon are formed conductor strips (5, 6, 7, 8) by applying a structure on an electrically conductive layer (3) applied on one side (2) of the support. A semiconductor power module can be manufactured easily and economically enabling several mounting technologies by using a homogeneous base support. Therefore, the conductor strips (5, 6, 7, 8), as integral elements of the conductor circuit have loose ends (6a, 7a, 8a) detached from the side (2) of the support, the ends of the conductor strips extending outside the support (1) and forming external connections.

### CROSS-REFERENCE TO RELATED APPLICATION

This application is a continuation of co-pending International Application No. PCT/EP2004/005450 filed May 21, 2004 which designates the United States, and claims priority to German application number DE 103 31 574.8 filed Jul. 11, 2003, which are incorporated herein by reference in their entirety.

### TECHNICAL FIELD

The invention lies in the field of external electrical connection technology for power semiconductor modules and relates to a power semiconductor module having a substrate, on which conductor tracks are formed by patterning an electrically conductive coating applied on a substrate side.

### BACKGROUND

In power semiconductor modules constructed in a known manner (e.g. DE 101 42 971 A1), at least one semiconductor component (e.g. IGBT) is arranged on the top side of a substrate and is contact-connected to conductor tracks on the top side of the substrate. The metallized (e.g. copper-coated) underside of the substrate can be pressed onto a cooling element for heat dissipation purposes. The substrate is surrounded by a (plastic) module housing and pressed onto the heat sink e.g. by means of screw connections.

In order to produce the conductor tracks, a metallization initially applied to the top side of the substrate is patterned by means of methods known per se (e.g. etching methods). Contact pins for external connection of the module are electrically connected, e.g. soldered, to the conductor tracks at predetermined points and/or at the conductor track ends.

This construction is complicated in terms of production engineering. Moreover, different base substrates are required depending on the desired contact-connection technology—e.g. surface contact-connection (also referred to hereinafter as SMT surface mounting technology) or contact-connection via connecting contact pins.

### SUMMARY

Therefore, it is an object of the present invention to provide a power semiconductor module which can be produced simply and cost-effectively and enables different mounting techniques using a uniform base substrate.

This object is achieved by a power semiconductor module comprising a substrate, on which conductor tracks are formed by patterning an electrically conductive coating applied on a substrate side, wherein the conductor tracks have, as integral conductor track constituent parts, free conductor track ends which are released from the substrate side and extend away from the substrate as external connections.

The substrate can be covered by a housing and the free conductor track ends may extend through the housing toward the outside. The conductor track ends may bear on a mounting side of the housing in such a way that they form SMT contacts. The conductor track ends can be shaped as plug-in elements.

In particular, the object is achieved by virtue of the fact that the conductor tracks have, as integral conductor track constituent parts, free conductor track ends which are released from the substrate side and extend away from the substrate as external connections.

One essential aspect of the invention is the direct continuous and one-piece connection of the integral connecting elements for external electrical connection to the conductor tracks. This obviates (internal) connections that are otherwise required between conductor track and separate connecting element, e.g. a contact pin. A power semiconductor module which is improved in terms of its electrical properties, namely has low inductance and low impedance, is thus created. Moreover, the structural height of the power semiconductor module is reduced. The connecting elements can advantageously be arranged comparatively closely and thus permit a high packing density of power semiconductor modules according to the invention.

Moreover, the reduced number of components to be handled and to be mounted considerably simplifies production and the omission of additional (internal) electrical connections reduces the risk of defective connections and thus increases the yield and reliability of the power semiconductor module according to the invention.

A further essential aspect of the invention is that the conductor track ends, owing to the fact that they are free and released from the top side of the substrate, can be bent away at a variable angle from the top side of the substrate and thus permit a flexible configuration. In particular, it is possible to provide connecting elements that are adapted depending on circuitry requirements in terms of number, form and type—e.g. designed both as control connections and as load connections. The connecting elements may be configured depending on the required current-carrying capacity.

In one advantageous development of the invention, the substrate is covered or surrounded by a housing in a manner known per se, the free conductor track ends advantageously extending through the housing toward the outside. The housing performs a dual function not just for the protection of the components and the substrate, rather it can mechanically support, route and protect the conductor track ends.

The conductor track ends emerging from the housing can then be bent over depending on the desired connection method—e.g. in a form suitable for SMT mounting—and be bent onto a mounting side of the housing. However, they may also be shaped into plug-in elements with a desired, e.g. pin- or lug-type configuration.

### BRIEF DESCRIPTION OF THE DRAWINGS

The invention will be explained in more detail below on the basis of the exemplary embodiments illustrated in the figures of the drawing, the same reference symbols being used for identical elements. In the figures:

FIG. 1 shows an exemplary embodiment of a power semiconductor module according to the invention in perspective view,

FIGS. 2 and 3 show cross-sectional views of the exemplary embodiment according to FIG. 1 with a housing,

FIGS. 4 to 6 show variants of a power semiconductor module according to the invention, and

FIGS. 7 and 8 show mounting possibilities for a power semiconductor module according to the invention.

### DETAILED DESCRIPTION

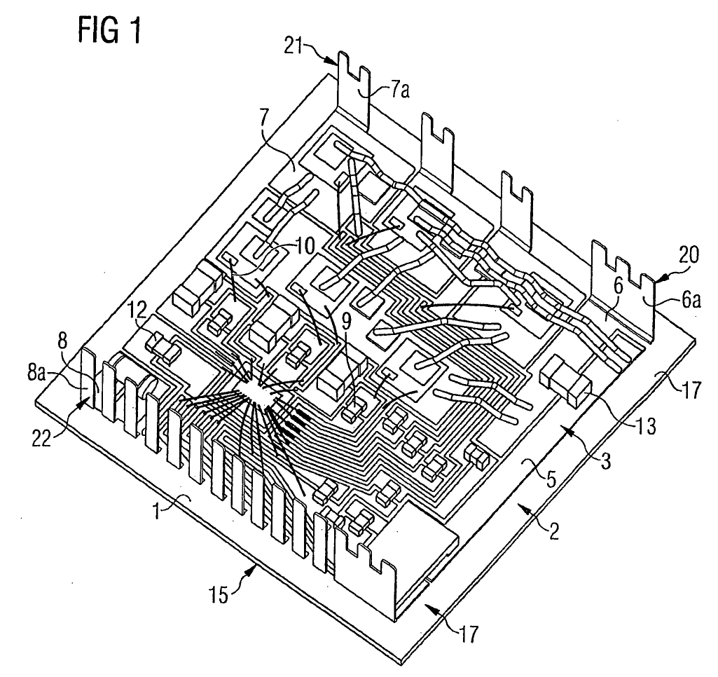

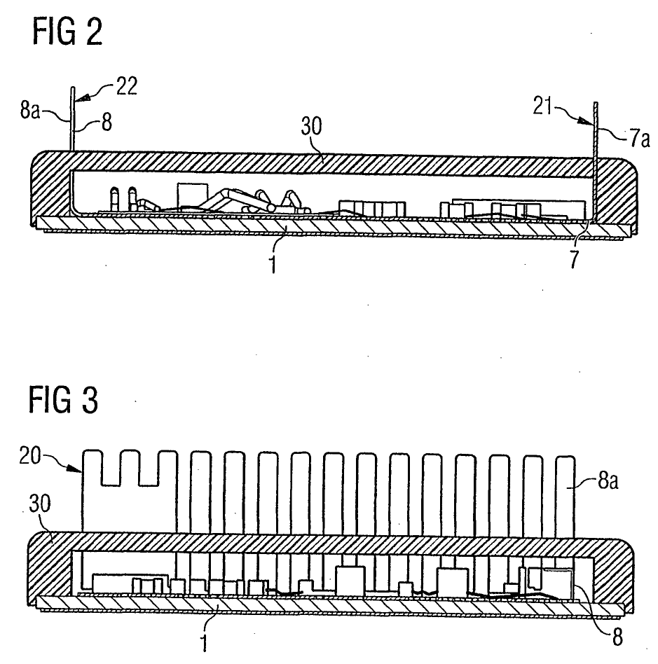

FIG. 1 shows a substrate 1, a top side metallization 3 composed of copper, for example, being applied on the top side 2 of said substrate 1. A structure of conductor tracks (e.g. 5, 6, 7, 8) and connecting contact areas (e.g. 9) is produced from said metallization by means of a patterning method known per se. Semiconductor components 12, 13 are mechanically and electrically connected to them by soldering or bonding wires 10. The semiconductor components may be IGBTs and/or diodes. The substrate 1 may be composed of ceramic and likewise be metallized at its underside 15 (also see FIG. 2).

The substrate forms a base substrate for a power semiconductor module that can be configured variously in terms of connection. For this purpose, in regions provided for external contact-connection, preferably in the edge region 17 of the substrate 1, some of the conductor tracks 6, 7, 8 are released from the top side 2 of the substrate and bent away by their thereby free conductor track ends 6a, 7a, 8a at right angles from the top side of the substrate. The conductor track ends form, in a manner given in even more detail below, integral external connecting elements 20, 21, 22 of the conductor tracks for external contact-connection (e.g. as control or load connections). An essential aspect in this case is the material-continuous one-piece connection of the conductor tracks 6, 7, 8 to the respective connecting element 20, 21, 22. The position and orientation of the connecting elements may be varied as required. The connecting elements may be realized e.g. as screw lugs, welding contacts, soldering contacts or contacts designed for SMT mounting.

By virtue of this configuration, production is significantly simplified, reliability is considerably increased owing to the obviation of additional connection locations between conductor tracks and connecting elements, a small structural height is realized in conjunction with very low-impedance and low-inductance behavior, and a high packing density of the power semiconductor module according to the invention is made possible.

FIGS. 2 and 3 show, in a cross-sectional illustration of the substrate 1 surrounded by a (thermosetting plastic) housing 30 in accordance with FIG. 1, the advantageous supporting function of the housing on the led-through conductor track ends 7a, 8a and 6a and thus on the connecting elements 20, 21, 22. The connecting elements are thereby mechanically stabilized sufficiently for a direct connection and can be finally shaped at a variable angle depending on the desired contact-connection technology.

Proceeding from the production state according to FIGS. 2 and 3, FIGS. 4 to 6 show variants with regard to the final shaping of the conductor track ends.

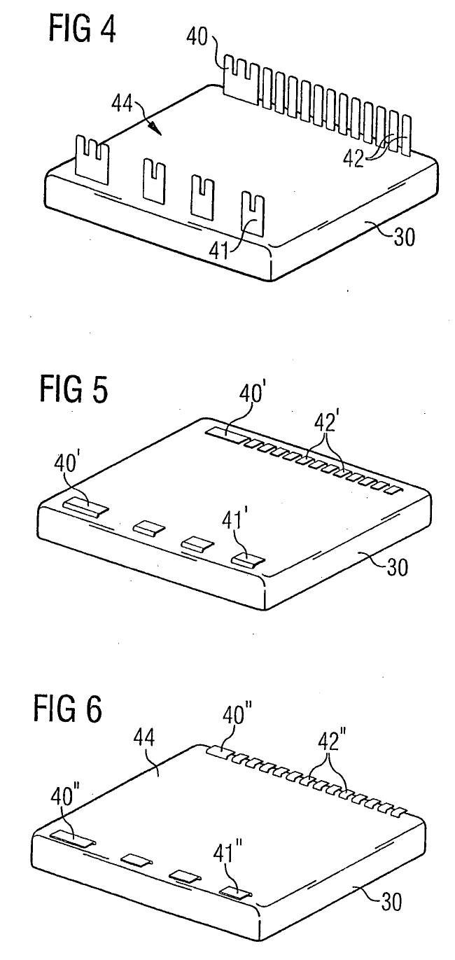

FIG. 4 essentially shows the configuration which can also already be discerned directly in FIGS. 2 and 3. Here conductor track ends shaped into multiply 40, doubly 41 or singly 42 pluggable or through-pluggable connecting contacts penetrate through the mounting side 44 of the housing 30. This power semiconductor module is thus configured as a “plug-in module”.

FIG. 5 shows a variant in which an SMT-enabled power semiconductor module is produced by bending over the conductor track ends 40′, 41′, 42′ inwardly onto the mounting side 44 of the housing 30.

FIG. 6 shows a variant in which an SMT-enabled power semiconductor module is produced by bending over the conductor track ends 40″, 41″, 42″ outwardly onto the mounting side 44 of the housing 30.

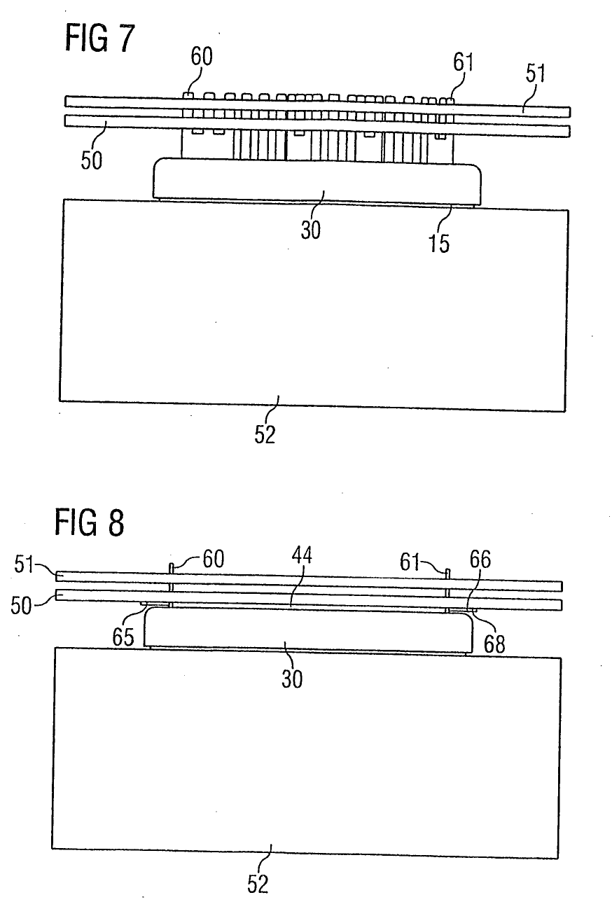

FIGS. 7 and 8 show side views of a power semiconductor module according to the invention which is mounted onto a printed circuit board (PCB) 50 and is additionally electrically connected to a conductor (busbar) 51. The power semiconductor module is mounted by the module or substrate underside 15 on a heat sink 52. As shown in FIG. 7, conductor track ends (connecting elements) 60, 61 of the power semiconductor module are designed, as described, in through-pluggable fashion for through-plating (so-called “through hole process”) and are plugged directly into the printed circuit board.

Conductor track ends (connecting elements) 65, 66 are designed for SMT connection (e.g. soldering). As shown in FIG. 8, these conductor track ends 65, 66 are soldering lugs bent outwardly onto the mounting side 44 of the housing 30.

These are soldered to corresponding contact locations on the printed circuit board at soldering locations 68. Conductor track ends can also be soldered or welded directly onto the busbar 51.

List of Reference Symbols

1 Substrate
2 Top side of substrate
3 Top side metallization
5, 6, 7, 8 Conductor tracks
6a, 7a, 8a Free conductor track ends
9 Connecting contact area
10 Bonding wire
12, 13 Semiconductor components
15 Underside
17 Edge region
20, 21, 22 Connecting elements
30 Housing
40, 41, 42 Conductor track ends
40′, 41′, 42′ Conductor track ends
40 ″, 41″, 42″ Conductor track ends
44 Mounting side
50 Printed circuit board
51 Conductor (busbar)
52 Heat sink
60, 61, 65, 66 Conductor track ends
68 Soldering locations

What is claimed is:

1. A power semiconductor module
comprising a substrate, on which conductor tracks are formed by patterning an electrically conductive coating applied on a substrate side,
wherein the conductor tracks have, as integral conductor track constituent parts, free conductor track ends which are released from the substrate side and extend away from the substrate as external connections.

2. A power semiconductor module according to claim 1, wherein the substrate is covered by a housing and the free conductor track ends extend through the housing toward the outside.

3. A power semiconductor module according to claim 2, wherein the conductor track ends bear on a mounting side of the housing in such a way that they form SMT contacts.

4. A power semiconductor module according to claim 2, wherein the conductor track ends are shaped as plug-in elements.

5. A power semiconductor module according to claim 3, wherein the conductor track ends are shaped as plug-in elements.

6. A power semiconductor module comprising a substrate, said substrate comprising an electrically conductive coating on a substrate side which is patterned in such a way that conductor tracks are formed, said conductor tracks have, as integral conductor track constituent parts, free conductor track ends which are released from the substrate side and extend away from the substrate as external connections.

7. A power semiconductor module according to claim 6, wherein the substrate is covered by a housing and the free conductor track ends extend through the housing toward the outside.

8. A power semiconductor module according to claim 7, wherein the free conductor track ends extend from said substrate at a right angle.

9. A power semiconductor module according to claim 7, wherein the conductor track ends bear on a mounting side of the housing in such a way that they form SMT contacts.

10. A power semiconductor module according to claim 7, wherein the conductor track ends are shaped as plug-in elements.

11. A power semiconductor module according to claim 8, wherein the conductor track ends are shaped as plug-in elements.

12. A power semiconductor module according to claim 9, wherein the conductor track ends are shaped as plug-in elements.
